(19) United States
(12) Patent Application Publication
(10) Pub. No.: US 2026/0332157 A1
(43) Pub. Date: Oct. 22, 2026

(54) SUCCESSIVE APPROXIMATION REGISTER ANALOG TO DIGITAL CONVERTER FAST BIT SWITCHING WITH LOW LEAKAGE

(71) Applicant: Analog Devices, Inc., Wilmington, MA (US)

(72) Inventors: Junhua Shen, Lexington, MA (US); Efram Burlingame, San Diego, CA (US)

(21) Appl. No.: 19/557,896

(22) Filed: Mar. 5, 2026

Related U.S. Application Data
(60) Provisional application No. 63/792,374, filed on Apr. 22, 2025.

(51) Int. Cl. H03M 1/46

(52) U.S. Cl. CPC H03M 1/466

(57) ABSTRACT

A switching technique for capacitor SAR ADC DACs enables use of low-threshold-voltage devices for high-speed settling while mitigating leakage between differential reference rails. A tri-statable gate driver drives a switch gate to its nominal rail according to a bit decision and is then tri-stated. A small coupling capacitor injects charge to shift the gate beyond the rail (e.g., pulling an NMOS gate below ground), placing the device in a deep-off state to suppress leakage for the remainder of the bit trial. Logic schemes generate enable and injection timing per branch using SAR sequencing signals and decision-dependent logic, including implementations compatible with reservoir-capacitor references and asynchronous SAR timing.

### RELATED APPLICATIONS

This application claims the benefit of priority to U.S. Provisional Patent Application No. 63/792,374 filed Apr. 22, 2025, and titled “SUCCESSIVE APPROXIMATION REGISTER ANALOG TO DIGITAL CONVERTER FAST BIT SWITCHING WITH LOW LEAKAGE”, the disclosure of which is incorporated herein by reference.

### BACKGROUND

### Technical Field

The present disclosure relates to analog-to-digital converters, and more particularly to switching circuits in successive approximation register (SAR)

### DESCRIPTION OF THE RELATED ART

Advanced CMOS processes provide multiple threshold-voltage device flavors, including high-Vt (HVT), standard-Vt (SVT), and low-Vt (LVT), which trade off switching speed and leakage. In SAR ADCs, DAC settling is a critical determinant of conversion speed, and LVT switches are preferred for their faster on-state performance, typically enabling significantly improved settling relative to SVT.

### SUMMARY

In embodiments a switching circuit for a capacitive digital-to-analog converter in a successive approximation register analog-to-digital converter includes a transistor switch having a gate node and configured to receive a gate drive signal to connect a bit capacitor to a reference voltage during a bit trial, a tri-statable driver configured to drive the gate node to a first rail corresponding to a bit decision; and a coupling network configured, after the driver is tri-stated, to capacitively inject charge to the gate node to shift a gate voltage beyond the first rail, thereby placing the transistor switch in a deep-off state to suppress leakage between differential reference rails during a remainder of the bit trial. The coupling network includes a coupling capacitor driven by an injection signal derived from SAR logic. The tri-statable driver is an inverter including series gating devices on pull-up and pull-down paths controlled by enable signals en and en_b. The gate voltage is shifted by about 100 to 200 millivolts beyond a supply rail. The transistor switch is an NMOS device and the coupling network shifts the gate voltage below ground. The transistor switch is a PMOS device and the coupling network shifts the gate voltage above VDD. The enable signals to tri-state the driver are derived from a SAR bit-trial sequencing signal. The coupling network injection timing is dependent on a bit decision signal. The capacitive digital-to-analog converter may employ a split-capacitor topology with pseudo-differential control lines. Embodiments are not limited to split capacitor topologies wherein convential bit switching circuits may be used. A reservoir capacitor provides a reference voltage source during bit trials. The tri-statable driver employs SVT devices sized to minimize additional leakage and avoid degrading edge rate. The coupling capacitor is a small fraction of a parasitic capacitance at the gate node. Additionally including logic circuitry configured to generate, for each of four per-bit branches in a split-capacitor cell, an injection signal and corresponding enable signals according to a first mapping scheme. The first mapping scheme reuses go and go_b as en_b and en for all four branches. Additionally including logic circuitry configured to generate, for each of four per-bit branches in a split-capacitor cell, an injection signal and corresponding enable signals according to a second mapping scheme that uses delayed versions of decision and branch signals. The SAR logic is asynchronous and provides a per-bit “go” sequencing signal reused for driver tri-stating and injection timing.

A method for operating a switching circuit in a SAR ADC capacitive DAC, including, during a bit trial, driving a switch gate to a first rail responsive to a bit decision; after the gate reaches the first rail, tri-stating a driver that sources and sinks the gate; and after tri-stating, capacitively coupling charge onto the gate to shift its voltage beyond the first rail to place the switch in a deep-off state to reduce leakage between differential reference rails during a remainder of the bit trial. Additionally, deriving a tri-stating enable from a SAR bit-trial sequencing signal and deriving injection polarity and timing from decision-dependent logic. The shifting comprises pulling an NMOS gate about 100-200 mV below ground or a PMOS gate above VDD. Implementing per-branch injection and enable signals for bp_i, bm_i, bp_n_i, and bm_n_i according to a mapping specified by one of a first logic scheme or a second logic scheme with delayed signals.

### BRIEF DESCRIPTION OF THE DRAWINGS

FIG. 1 is a block diagram of a SAR (successive approximation register) ADC (analog to digital converter) diagram, according to an embodiment of the instant disclosure.

FIG. 2 shows one bit trial for an SAR DAC conversion, according to an embodiment of the instant disclosure.

FIG. 3 is a schematic of a bit cell used in a SAR DAC, according to an embodiment of the instant disclosure.

FIG. 4 is a schematic of a bit cell with split capacitors, according to an embodiment of the instant disclosure.

FIG. 5 is a schematic of a low leakage switching circuit, according to an embodiment of the instant disclosure.

FIG. 6 is a schematic of a tri-statable state driver such as 520 from FIG. 5, according to an embodiment of the instant disclosure.

FIG. 7 is a timing diagram, according to an embodiment of the instant disclosure.

FIG. 8 is a logic circuit generating logic signals for the circuits of FIG. 5 in an embodiment of the instant disclosure.

FIG. 9 shows a logic circuit for a second approach according to an embodiment of the instant disclosure.

While the methods and mechanisms described herein are susceptible to various modifications and alternative forms, specific embodiments are shown by way of example in the drawings and are herein described in detail. It should be understood, however, that drawings and detailed description thereto are not intended to limit the methods and mechanisms to the particular form disclosed, but on the contrary, are intended to cover all modifications, equivalents and alternatives apparent to those skilled in the art once the disclosure is fully appreciated.

### DETAILED DESCRIPTION

In the following description, numerous specific details are set forth to provide a thorough understanding of the methods and mechanisms presented herein. However, one having ordinary skill in the art should recognize that the various embodiments may be practiced without these specific details. In some instances, well-known structures, components, signals, computer program instructions, and techniques have not been shown in detail to avoid obscuring the approaches described herein. It will be appreciated that for simplicity and clarity of illustration, elements shown in the figures have not necessarily been drawn to scale. For example, the dimensions of some of the elements may be exaggerated relative to other elements.

This specification includes references to “one embodiment”. The appearance of the phrase “in one embodiment” in different contexts does not necessarily refer to the same embodiment. Particular features, structures, or characteristics may be combined in any suitable manner consistent with this disclosure. Furthermore, as used throughout this application, the word “may” is used in a permissive sense (i.e., meaning having the potential to), rather than the mandatory sense (i.e., meaning must). Similarly, the words “include”, “including”, and “includes” mean including, but not limited to.

Terminology. The following paragraphs provide definitions and/or context for terms found in this disclosure (including the appended claims):

“Comprising.” This term is open-ended. As used in the appended claims, this term does not foreclose additional structure or steps. Consider a claim that recites: “A system comprising an amplifier . . . ” Such a claim does not foreclose the system from including additional components (e.g., a capacitor, a resistor, a central processing unit).

“Configured To.” Various units, circuits, or other components may be described or claimed as “configured to” perform a task or tasks. In such contexts, “configured to” is used to connote structure by indicating that the units/circuits/components include structure (e.g., circuitry) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. § 112, paragraph (f), for that unit/circuit/component. Additionally, “configured to” can include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

In general, advanced CMOS processes provide multiple threshold-voltage devices, including high-Vt (HVT), standard-Vt (SVT), and low-Vt (LVT), which trade off switching speed and leakage. Traditionally for SAR (successive approximation register) ADCs (analog to digitsal converters), DACs (digital to analog conversters), settling is a critical determinant of conversion speed. Typically, LVT switches are preferred for their faster on-state performance, generally enabling significantly improved settling relative to SVT, however, the increased subthreshold leakage of nominally off LVT devices can form parasitic current paths between differential references (VREFP and VREFM) during bit trials, degrading accuracy and causing undesired droop, particularly when a reservoir capacitor is used as a reference source during conversion.

In most embodiments split-capacitor DAC architectures sample against VREFP and VREFM to achieve an effective common-mode equivalent without explicitly driving a mid-supply VCM node, thereby preserving switch overdrive and speed; nevertheless, the leakage problem persists in the off branch during conversion.

In some embodiments LVT bit switches are used for high-speed SAR DAC operation while substantially mitigating leakage by temporarily tri-stating the gate driver and capacitively boosting the switch gate voltage away from its nominal rail after the bit decision is made.

In many embodiments the gate driver for a given bit-switch branch is tri-stated responsive to a SAR logic sequencing signal (e.g., go/go_b) and a small capacitive coupling injects charge onto the gate node to pull the NMOS gate slightly below ground and/or the PMOS gate slightly above VDD, thereby placing the off device in a deep-off region and dramatically reducing leakage across the reference rails.

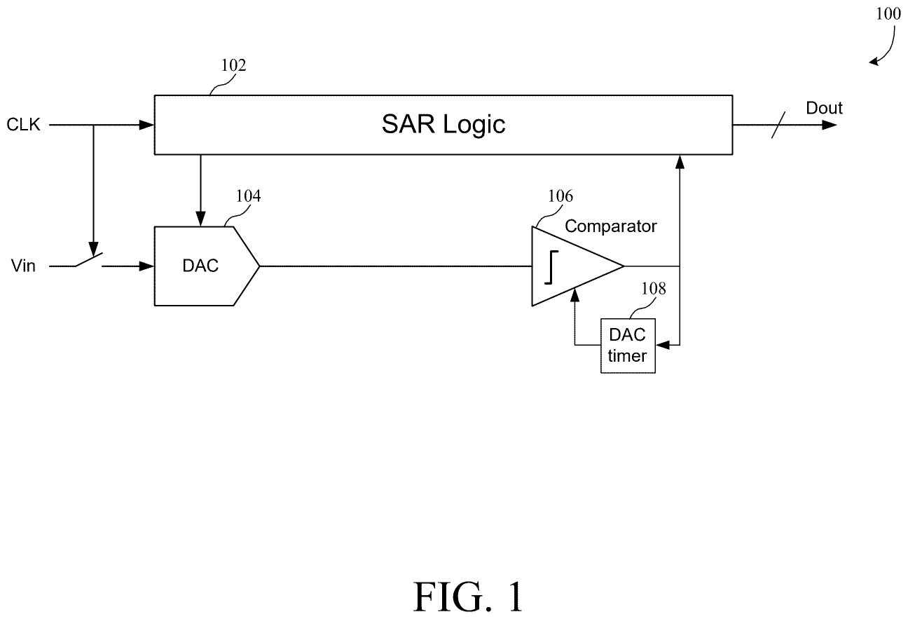

FIG. 1 is a block diagram of a SAR (successive approximation register) ADC (analog to digital converter) diagram, according to an embodiment of the instant disclosure. The block diagram shows a typical SAR ADC diagram where the comparator, SAR logic102, and DAC 104 form a feedback loop. SAR ADC comprises a comparator 106, SAR logic, and a capacitive DAC arranged in a feedback loop to sequentially resolve bit decisions during a conversion interval determined in part by a timer 108.

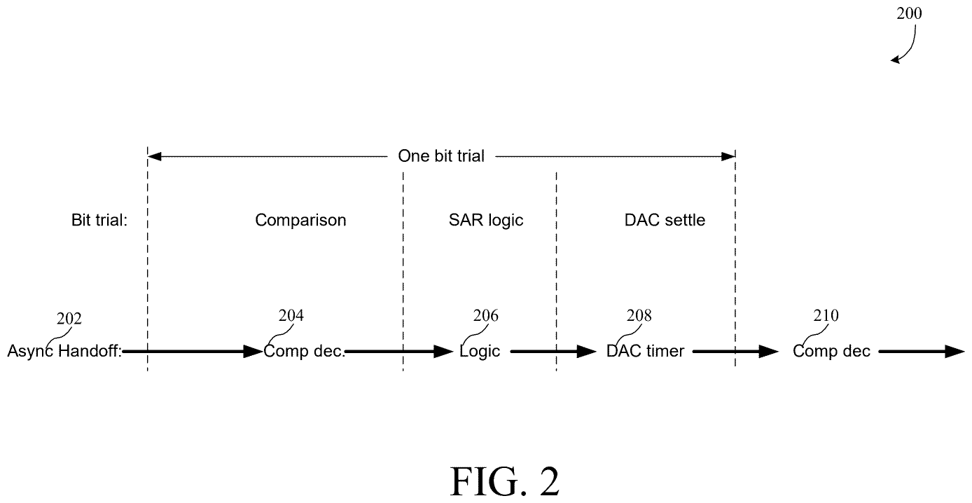

FIG. 2 shows one bit trial for an SAR ADC conversion, according to an embodiment of the instant disclosure. A bit is asynchronously handed off 202 which then starts a comparison 204. The conversion continues with a successive approximation through the SAR logic 206. The DAC settles 208 for a period of time determined by a timer. The comparison is complete after the timer triggers 210. It shows that each bit trial proceeds with a decision on a bit, which then determines how the DAC reconnects the associated bit-capacitor element to one of the references, iteratively converging to the final digital code. It also illustrates the sequential operation of each bit trial. To increase the SAR ADC operating speed, improving DAC settling time is as critical as improving comparator and SAR logic speed. In an N-bit SAR ADC, the DAC nominally comprises N bit capacitors each with associated bit switches.

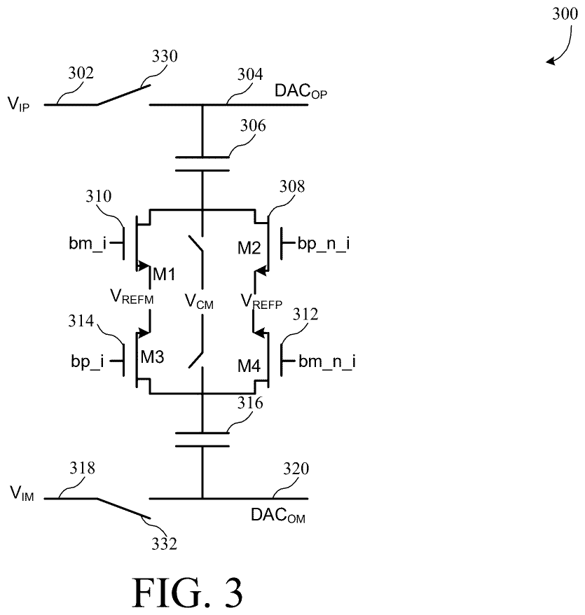

FIG. 3 is a schematic of a bit cell used in a SAR DAC, according to an embodiment of the instant disclosure. An input VI 302 is electrically coupled through a sample switch 330 to DAC_{OP} 304 which in turn is electrically coupled to one side of capacitor 306. The other side of capacitor 306 is electrically coupled to the drain of transistor M1 310 and is electrically coupled to the drain of transistor M2 308. The gate of transistor 310 is electrically coupled to control signal bm_i. The gate of transistor 308 is electrically coupled to the control signal bp_n_i. The source of transistor M1 310 is electrically coupled to VREFM which is turn is electrically coupled to the source of transistor M3 314. The source of transistor M2 308 is electrically coupled to V_{REFP} which in turn is electrically coupled to the source of transistor M4 312. The gate of transistor M3 is electrically coupled to the control signal bp_i. The gate of transistor M4 312 is electrically coupled to the control signal bm_n_i. The drain of transistor M3 314 is electrically coupled to the drain of transistor M4 312 and is electrically coupled to one side of capacitor 316. The other end of capacitor 316 is electrically coupled to DAC_{OM} 320 which is electrically coupled to switch 332 which in turn is electrically coupled to VIM 318.

The schematic illustrates a bit cell, the sampling phase connects the capacitor to the input differential pair against a common-mode, and during conversion, one of the two differential reference paths is engaged depending on the decision; when LVT transistors are used to accelerate settling, the off device exhibits substantial subthreshold leakage. FIG. 3 illustrates one such bit cap and switch unit. During the ADC sampling phase, capacitors 306 and 316 may sample the input voltage with both VCM and VI/VIM switches turned on while the other bit switches shown remain off. During the conversion phase, either M2/M3 turn on if the bit decision is 1 or M1/M4 turn on if the bit decision is 0. To achieve faster DAC settling, LVT switches are highly preferred as they could operate roughly 2× faster than SVT. The downside of using LVT devices, as alluded earlier, is that they leak much more. In this case, one of M1/M2 (or M3/M4) is on and the other is off. Due to the leaky nature of the off device, there is a leakage path between VREFP and VREFM. It is essential that we mitigate the leakage while maintaining the speed advantage of using LVT devices.

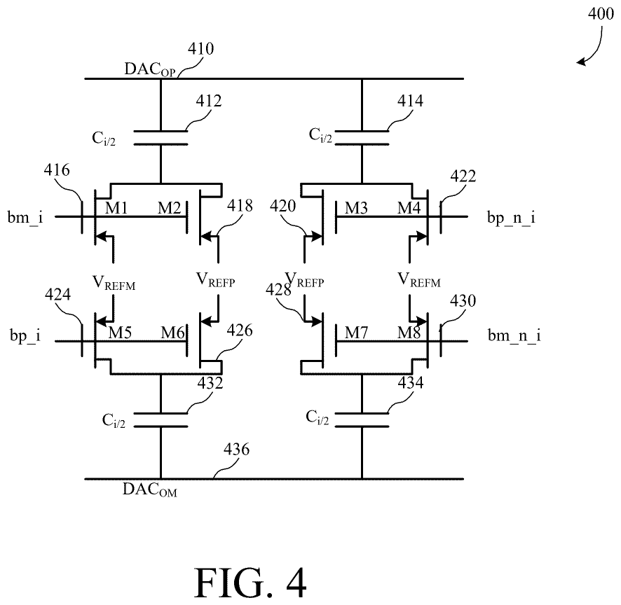

FIG. 4 is a schematic of a bit cell with split capacitors, according to an embodiment of the instant disclosure. The signal DACOP 410 is electrically coupled to capacitor 412. The other end of capacitor 412 is electrically coupled to the drain of transistor M1 416 and is electrically coupled to the drain of transistor M2 418. The source of transistor M1 is electrically coupled to V_{REFM}. The source of transistor M2 418 is electrically coupled to V_{REFP}. The gate of transistor M1 is electrically coupled to the gate of transistor M2 418 and is electrically coupled to signal bm_i. V_{REFM} is electrically coupled to the source of transistor M5 424. VREFP is electrically coupled to the source of transistor M6 426. The drain of transistor M5 424 is electrically coupled to transistor M6 426 and is electrically coupled to capacitor 432 which in turn is electrically coupled to DAC_{OM} 436. The gate of transistor M5 424 is electrically coupled to the gate of transistor 426 and is electrically coupled to bp_i. The signal DACOP 410 is electrically coupled to capacitor 414. The other end of capacitor 414 is electrically coupled to the drain of transistor M3 420 and is electrically coupled to the drain of transistor M4 422. The source of transistor M3 420 is electrically coupled to V_{REFP}. The source of transistor M4 422 is electrically coupled to V_{REFM}. The gate of transistor M3 420 is electrically coupled togate of transistor M4 422 and is electrically coupled to signal bp_n_i. V_{REFP} is electrically coupled to the source of transistor M7 428. V_{REFM} is electrically coupled to the source of transistor M8 430. The drain of transistor M7 428 is electrically coupled to transistor M8 430 and is electrically coupled to capacitor 434 which in turn is electrically coupled to DAC_{OM} 436. The gate of transistor M7 428 is electrically coupled to the gate of transistor M8 430 and is electrically coupled to bm_n_i.

For the switching scheme in FIG. 4, the bit cap Ci (along with other bit caps—not illustrated) is split into two halves, 412 and 414 along with 432 and 434. During the sampling phase, half of the bit cap sample input against VREFP, the other half against VREFM. Equivalently, Ci is sampling against VCM ((VREFP+VREFM)/2) without using VCM as the middle voltage would slow down switching speed significantly. During the conversion phase, either two bp control lines go from 0 to 1 if the bit decision is 1, or two bm control lines go from 0 to 1 if the bit decision is 0. Typically, the control lines are from the SAR logic with inverter acting as buffers driving the corresponding bit switches. Cres is used as reference during bit trial to minimize DAC settling speed though it is more susceptible to leakage.

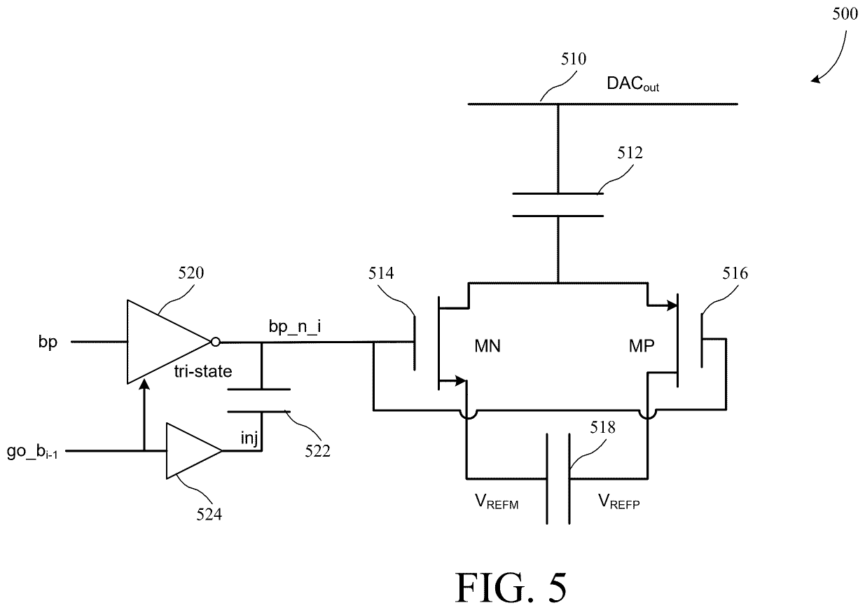

FIG. 5 is a schematic of a low leakage switching circuit, according to an embodiment of the instant disclosure. DACout 510 is electrically coupled to one side of capacitor 512. The other end of capacitor 512 is electrically coupled to the drain of transistor 514 and is electrically coupled to the source of transistor 516. The drain of transistor 516 is electrically coupled to one side of capacitor 518 and is electrically coupled to V_{REFP}. The other end of capacitor 518 is electrically coupled to the source of transistor 514 nd is electrically coupled to the signal V_{REFM}. The gate of transistor 516 is electrically coupled to the gate of transistor 514 is electrically coupled to the output of inverting buffer 520 and electrically coupled to capacitor 522. The other side of capacitor 522 is electrically coupled to the output of buffer 524 and is electrically coupled to the signal inj. The input of buffer 524 is electrically coupled to the tri state control of inverting buffer 520. The input of buffer 520 is electrically coupled to control input bp. The input of buffer 524 is electrically coupled to the control signal go_bᵢ₋₁.

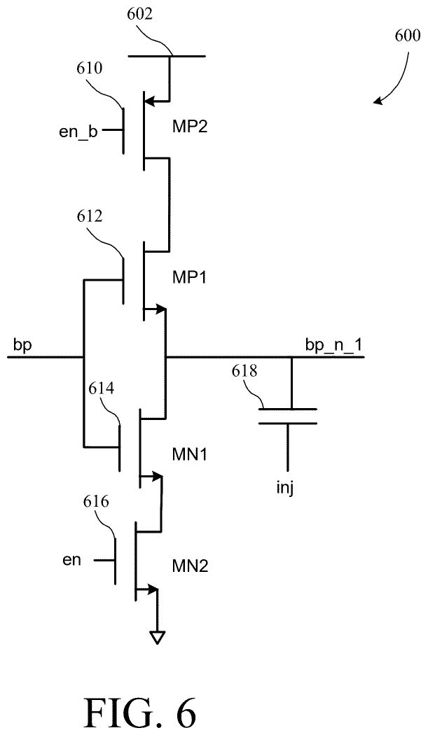

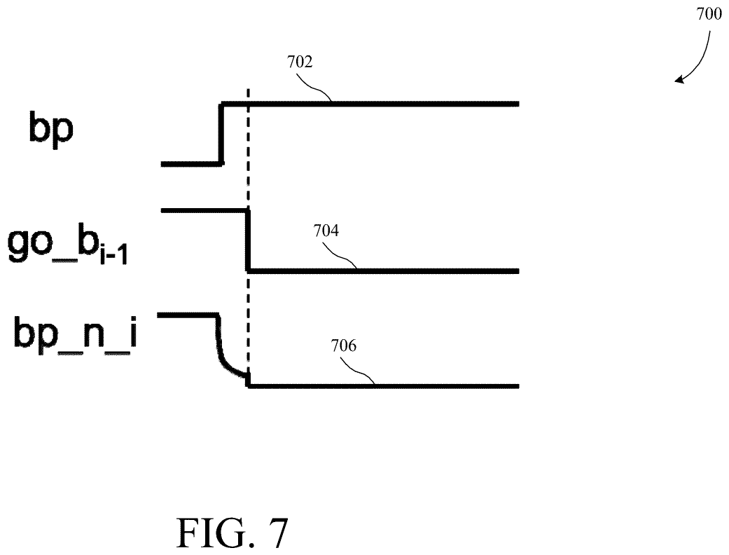

Only one branch of bit switching circuit shown in FIG. 5 and is included here for simplicity. Bit switches MP and MN are of the type LVT for fast DAC settling. Introduced here is a small coupling cap Cc 522 and leverage an existing SAR logic sequencing signal go (a variant go_b is used in this illustration) to achieve low leakage between VREFP and VREFM through switches MP and MN. The sequencing go signal is needed in an asynchronous SAR ADC to track which bit trial is active so we can readily reuse the signal in these embodiments. The driving inverter is customized to be tri-statable as shown in FIG. 6. The go signal typically comes a bit after the decision bp signal. As illustrated in FIG. 7, shortly after switch MN turns off at the transition of bp going low to high, go signal comes and tri-states the driving inverter before capacitively coupling a small amount to switch gate voltage bp_n_i. This puts the off switch MN in deep off region as its gate voltage goes below ground. In practice, the deltaV coupled onto bp_n_i could be on the order of 100 mV-200 mV to balance leakage mitigation and device reliability. The tri-state switches introduced in the driving inverter may be relatively big and using SVT devices to not slow down the driving or provide a leakage path for bp_n_i. The coupling cap Cc is a small fraction of the existing parasitic cap at the bp_n_i node as only a small deltaV is needed. The go signal timing is not critical as small amount of leakage through MN is tolerated for given ADC accuracy target.

FIG. 6 is a schematic of a tri-statable state driver such as 520 from FIG. 5, according to an embodiment of the instant disclosure. The voltage rail is electrically coupled to the emitter of transistor MP2 610. The gate of transistor MP 2 610 is electrically coupled to the control signal en_b. The drain of transistor MP 2 610 is electrically coupled to the drain of transistor MP 1 612. The source of transistor MP1 612 is electrically coupled to the drain of transistor MN 1 614, is electrically coupled to one end of capacitor 618 and is electrically coupled to bp_n_1. The gate of transistor MP 1 612 is electrically coupled to the gate of transistor MN1 614 and is electrically coupled to bp. The source of transistor of transistor MN 1 614 is electrically coupled to the drain of transistor MN2 616. The gate of transistor 616 is electrically coupled to en. The source of transistor MN2 616 is electrically coupled to circuit ground.

FIG. 7 is a timing diagram, according to an embodiment of the instant disclosure. The diagram shows the relationship between bp 702 go_bᵢ₋₁ 704 and bp_n_i 706.

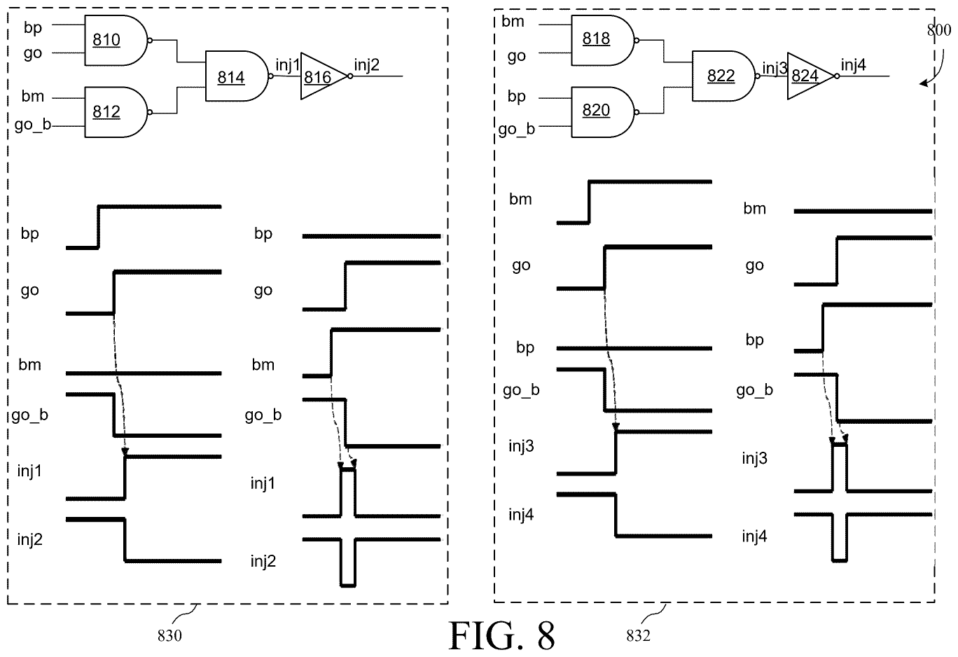

FIG. 8 is a logic circuit generating logic signals for the circuits of FIG. 5800, in an embodiment of the instant disclosure. The NAND gate 810 first input is electrically coupled to the signal bp. The second input of NAND gate 810 is electrically coupled to the signal go. The output of NAND gate 810 is electrically coupled to the first input of NAND gate 814. The first input of NAND gate 812 is electrically coupled to the signal bm. The second input of NAND gate 812 is electrically coupled to the signal go_b. The output of NAND gate 812 is electrically coupled to the second input of NAND gate 814. The output of NAND gate 814 is electrically coupled to the inverter 816 and is electrically coupled to the signal inj1. The output of inverter 816 is electrically coupled to the signal inj2. The NAND gate 818 first input is electrically coupled to the signal bm. The second input of NAND gate 818 is electrically coupled to the signal go. The output of NAND gate 818 is electrically coupled to the first input of NAND gate 822. The first input of NAND gate 820 is electrically coupled to the signal bp. The second input of NAND gate 820 is electrically coupled to the signal go_b. The output of NAND gate 820 is electrically coupled to the second input of NAND gate 822. The output of NAND gate 822 is electrically coupled to the inverter 824 and is electrically coupled to the signal inj3. The output of inverter 816 is electrically coupled to the signal inj4.

The logic circuit in FIG. 8 830 generates injection signal inj1 and inj2 for bp_i and bm_i (FIG. 5) respectively, while the logic circuit in FIG. 8 832 generates injection signal inj3 and inj4 for bp_n_i and bm_n_i (FIG. 5) respectively. The go and go_b signals are re-used as en_b and en respectively for all four driving inverters for bp_i/bm_i/bp_n_i/bm_n_i to tri-state the inverters. If the bit decision is 1 (830, bp goes from 0 to 1 during the bit trial), inj1 goes from low to high after go rising edge, coupling deltaV onto gate of M5/M6 in FIG. 5 to dramatically reduce the leakage in the M6-M5 path by increasing their gate voltage bp_i to slightly above VDD. The inj1 edge occurs after go (reused as en_b as mentioned earlier) rising to make sure the driving inverter is tri-stated before coupling happens. If instead the bit decision is 0 832, bm goes from 0 to 1 during the bit trial), inj1 goes from low to high triggered by bm rising. This could couple some charge onto the gate of M5/M6, but this coupling happens before the driving inverter is tri-stated (triggered by go rising), so any coupling is absorbed by the driving inverter. Shortly afterwards, inj1 goes from high to low, triggered by go_b (also tri-states inverter) falling edge. This brings the gate voltage of M5/M6 bp_i to slightly below ground thus significantly reduce M6-M5 path leakage. For bm_i, inj2 shown in FIGS. 830 and 832 is used for coupling instead of inj1. Likewise, 832 shows injection signal generation for bp_n_i and bm_n_i. The mapping relationship is summarized in Table 1.

TABLE 1

| | bp_i | bm_i | bp_n_i | bm_n_i |
|---|---|---|---|---|
| inj | inj1 | inj2 | inj3 | inj4 |
| en | go_b | go_b | go_b | go_b |
| en_b | go | go | go | go |

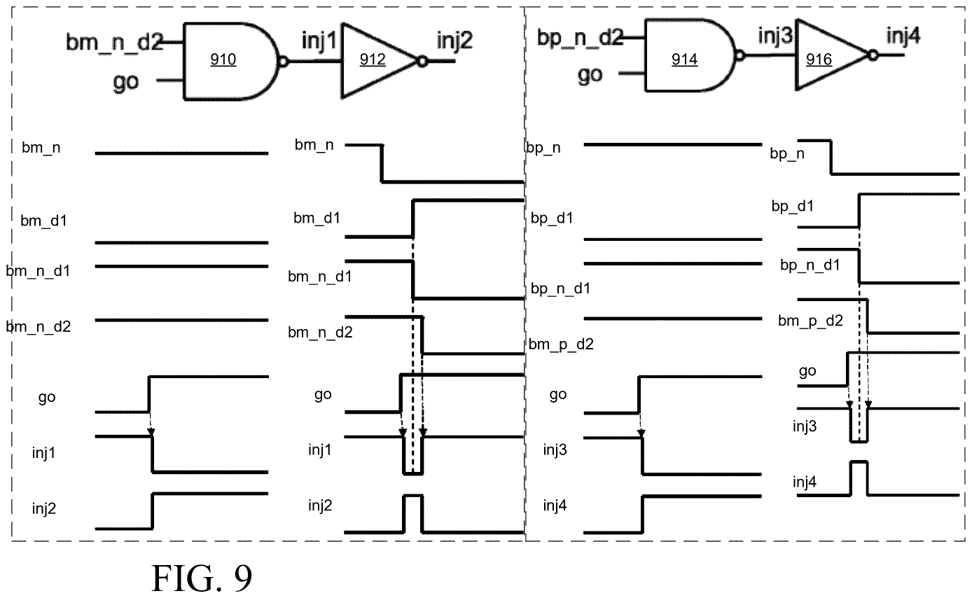

FIG. 9 shows a logic circuit for a second approach according to an embodiment of the instant disclosure. The first input of NAND gate 910 is electrically coupled to the signal bm_n_2. The second input of NAND gate 910 is electrically coupled to the signal go. The output of NAND yats 910 is electrically coupled to the inverter 912 and is electrically coupled to the signal inj1. The output of inverter 912 is electrically coupled to inj2. The first input of NAND gate 914 is electrically coupled to the signal bp_n_d2. The second input pf NAND gate 914 is electrically coupled to the signal go. The output of NAND gate 914 is electrically coupled to the input of inverter 916 and is electrically coupled to the signal inj3. The output of inverter 916 is electrically coupled to the signal inj4.
In the logic the signal name with_d1 indicates a delayed version, d2 indicates further delayed signal. This approach requires fewer gates though delayed versions need to be generated for select signals. Table 2 summarizes the mapping relationship between the driving inverter's control signals and the signals generated by these logic circuits.

TABLE 2

| | bp_i | bm_i | bp_n_i | bm_n_i |
|---|---|---|---|---|
| inj | inj2 | inj4 | inj1 | inj3 |
| en | bm_n_d1 | bp_n_d1 | inj1 | inj3 |
| en_b | inj2 | inj4 | bm_d1 | bp_d1 |

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A switching circuit for a capacitive digital-to-analog converter in a successive approximation register analog-to-digital converter, comprising: a transistor switch having a gate node configured to receive a gate drive signal to connect a bit capacitor to a reference voltage during a bit trial; a tri-statable driver configured to drive the gate node to a first rail corresponding to a bit decision; and a coupling network configured, after the driver is tri-stated, to capacitively inject charge to the gate node to shift a gate voltage beyond the first rail, thereby placing the transistor switch in a deep-off state to suppress leakage between differential reference rails during a remainder of the bit trial phase.

2. The switching circuit of claim 1, wherein the coupling network comprises a coupling capacitor driven by an injection signal derived from SAR logic.

3. The switching circuit of claim 1, wherein the tri-statable driver is an inverter including series gating devices on pull-up and pull-down paths controlled by enable signals en and en_b.

4. The switching circuit of claim 1, wherein the gate voltage is shifted to a voltage beyond a supply rail.

5. The switching circuit of claim 1, wherein the transistor switch is an NMOS device and the coupling network shifts the gate voltage below ground.

6. The switching circuit of claim 1, wherein the transistor switch is a PMOS device and the coupling network shifts the gate voltage above VDD.

7. The switching circuit of claim 1, wherein enable signals to tri-state the driver are derived at least in part from a SAR bit-trial sequencing signal.

8. The switching circuit of claim 1, wherein the coupling network injection timing is dependent on a bit decision signal.

9. The switching circuit of claim 1, wherein the capacitive digital-to-analog converter employs a split-capacitor topology with pseudo-differential control lines.

10. The switching circuit of claim 1, wherein a reservoir capacitor provides a reference voltage source during bit trials.

11. The switching circuit of claim 1, wherein the tri-statable driver employs SVT devices sized to minimize additional leakage and avoid degrading edge rate.

12. The switching circuit of claim 1, wherein the coupling capacitor is a small fraction of a parasitic capacitance at the gate node.

13. The switching circuit of claim 1, further comprising logic circuitry configured to generate, for each of four per-bit branches in a split-capacitor cell, an injection signal and corresponding enable signals according to a first mapping scheme.

14. The switching circuit of claim 13, wherein the first mapping scheme reuses go and go_b as en_b and en for all four branches.

15. The switching circuit of claim 1, further comprising logic circuitry configured to generate, for each of four per-bit branches in a split-capacitor cell, an injection signal and corresponding enable signals according to a second mapping scheme that uses delayed versions of decision and branch signals.

16. The switching circuit of claim 1, wherein the SAR logic is asynchronous and provides a per-bit “go” sequencing signal reused for driver tri-stating and injection timing.

17. A method for operating a switching circuit in a SAR ADC capacitive DAC, comprising: during a bit trial, driving a switch gate to a first rail responsive to a bit decision; after the gate reaches the first rail, tri-stating a driver that sources and sinks the gate; and after tri-stating, capacitively coupling charge onto the gate to shift its voltage beyond the first rail to place the switch in a deep-off state to reduce leakage between differential reference rails during a remainder of the bit trial phase.

18. The method of claim 17, further comprising deriving a tri-stating enable from a SAR bit-trial sequencing signal and deriving injection polarity and timing from decision-dependent logic.

19. The method of claim 17, wherein shifting comprises pulling an NMOS gate to a voltage below ground or a PMOS gate above VDD.

20. The method of claim 17, further comprising implementing per-branch injection and enable signals for bp_i, bm_i, bp_n_i, and bm_n_i according to a mapping specified by one of a first logic scheme or a second logic scheme with delayed signals.
